(19) United States
(12) Patent Application Publication
(10) Pub. No.: US 2007/0196975 A1
(43) Pub. Date: Aug. 23, 2007

(54) Metal-Polishing Liquid And Polishing Method Using The Same

(75) Inventors: Yutaka Nomura, Ibaraki (JP); Hiroki Terazaki, Ibaraki (JP); Hiroshi Ono, Ibaraki (JP); Yasuo Kamigata, Ibaraki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: HITACHI CHEMICAL CO., LTD., Tokyo (JP)

(21) Appl. No.: 11/578,181

(22) PCT Filed: Apr. 12, 2005
(86) PCT No.: PCT/JP05/07065

§ 371 Date: Oct. 11, 2006

(30) Foreign Application Priority Data
Apr. 12, 2004 (JP) 2004-116694
Dec. 7, 2004 (JP) 2004-354585

(51) Int. Cl. H01L 21/8238

(52) U.S. Cl. 438/230

(57) ABSTRACT

The present invention provides a metal-polishing liquid, comprising polishing particles and a chemical component, wherein the polishing particles have charges of surface potential of the same polarity as the charges of surface potential on the reaction layer, adsorption layer or the mixed layer thereof formed by the chemical component on a metal to be polished with the metal-polishing liquid, and a polishing method using the same, that enable to give highly flattened surface at high Cu-polishing speed and enable reduction of the number of the polishing particles remaining on the polished face after polishing.

### TECHNICAL FIELD

The present invention relates to a metal-polishing liquid and a polishing method using the same.

### BACKGROUND ART

Along with increase in density and improvement in performance of semiconductor integrated circuits (hereinafter, referred to as LSI's), new microfabrication methods are recently under development. Chemical mechanical polishing (hereinafter, referred to as CMP) is one of such methods, and has been used widely for flattening interlayer dielectrics, forming metal plugs, and implanting wiring in LSI production process, in particular in multilayered wiring-forming step (see, for example, U.S. Pat. No. 4,944,836).

Recently, use of a copper alloy as the wiring material is studied for improvement in performance of LSI's. However, it is difficult to perform microfabrication on such a copper alloy by dry etching, which has been used conventionally, frequently in forming aluminum alloy wiring. For that reason, for example, the so-called damascene method of forming an implanted wiring by depositing a copper alloy thin film on a dielectric film having previously-formed grooves, thus implanting the copper alloy in the grooves, and removing the copper alloy thin film in the area other than the grooves by CMP is widely used (see, for example, Japanese Patent Application Laid-Open No. 2-278822).

In the general method of metal CMP, a polishing pad is bonded on a circular polishing table (platen); the polishing pad surface is wetted with a metal-polishing liquid; the metal film-formed face of a substrate is placed on the face of the polishing pad under pressure; the polishing table is rotated while a particular pressure (hereinafter, referred to as polishing pressure) is applied from back; and the convex portions of the metal film are removed by mechanical friction thereof with the polishing liquid.

The metal-polishing liquid used in CMP generally contains an oxidizer and polishing particles, and additionally, for example, a metal oxide dissolving agent and a protective film-forming agent as needed. The basic mechanism of CMP seems that the metal film surface is first oxidized by oxidation and the oxidized layer is then removed by abrasion with polishing particles. The oxidized layer of the surface of the metal in concave portions does not become in much contact with the polishing pads and thus does not removed by the polishing particles, and consequently, the substrate surface becomes flattened as the metal layer in the convex portions are removed along the progress of CMP (see, for example, F. B. Kaufman et al., “Chemical-Mechanical Polishing for Fabricating Patterned W Metal Features as Chip Interconnects”, Journal of the Electrochemical Society, 138, 11 (1991), p. 3460 to 3464).

However, formation of implanted wiring by CMP by using a metal-polishing liquid containing traditional polishing particles causes problems such as (1) deterioration in flatness by aphenomenon of the implanted metal wiring being scraped in the dish shape as the central area on the surface of the wiring is polished isostatically (hereinafter, referred to as dishing) or a phenomenon of interlayer dielectric film being polished with the wiring metal, forming dents (hereinafter, referred to as erosion), and (2) complexity of the cleaning step for removing the polishing particles remaining on the substrate surface after polishing.

To overcome the deterioration in flatness and to form highly reliable LSI wiring by preventing dishing, erosion, polishing scratch, and the like, for example, a method of using a metal-polishing liquid containing a metal oxide dissolving agent, an aminoacetic acid such as glycine or an amidosulfuric acid, and a protective film-forming agent such as BTA (benzotriazole) was proposed (see, for example, Japanese Patent Application Laid-Open No. 8-83780).

However, improvement in flatness byprotective film formation for example with BTA, which occasionally results in remarkable decrease not only in dishing and erosion but also in polishing speed, is not always desirable.

On the other hand, the polishing particles attached on the substrate during CMP treatment are normally removed by physical cleaning, for example, with PVA resin brush or by ultrasonication. However, as the polishing particles attached on the substrate became finer, there is increasing difficulty in making such a physical force act on the polishing particles effectively.

To solve the problem in the cleaning efficiency of polishing particles, there were proposed methods for removing polishing particles attached on the substrate such as a method of increasing cleaning efficiency by adding a surfactant to washing solution and making the polishing particles and the substrate have charges of the same polarity by changing the pH of washing solution (see, for example, Japanese Patent Application Laid-Open No. 8-107094).

### SUMMARY OF THE INVENTION

As described above, use of BTA, which has an extremely high protective film-forming efficiency, is accompanied not only with dishing and erosion but also drastic deterioration in polishing speed. Thus, there exists a need for a metal-polishing liquid that is sufficiently resistant to dishing and erosion as well as to deterioration in CMP speed.

Alternatively, addition of the surfactant described above often resulted in problems such as deposition of the surfactant itself on the substrate, leading to spread of contamination. And ineffectiveness of the surfactant depends on the combination with the polishing liquid employed.

The present invention provides a metal-polishing liquid and a polishing method using the same that allow to give highly flattened surface at high Cu-polishing speed,.

The present invention also provides a metal-polishing liquid and a polishing method using the same that allow reduction in the amount of the polishing particles remaining on the substrate surface after polishing.

The present invention relates to (1) a metal-polishing liquid, comprising polishing particles and a chemical component, wherein the polishing particles have charges of surface potential of the same polarity as the charges of surface potential on the reaction layer, adsorption layer or the mixed layer thereof formed with the chemical component on a metal to be polished with the metal-polishing liquid.

The present invention also relates to (2) a metal-polishing liquid, comprising polishing particle, wherein the charges of surface potential of the polishing particles and the charges of surface potential on a metal to be polished with the metal-polishing liquid are of the same polarity.

The present invention also relates to (3) the metal-polishing liquid described in (1) above, wherein the product of the surface potential of the reaction layer, adsorption layer or the mixed layer thereof (mV) and the surface potential of the polishing particle (mV) is 1 to 10,000.

The present invention also relates to (4) the metal-polishing liquid described in (2) above, wherein the product of the surface potential of the metal to be polished (mV) and the surface potential of the polishing particle (mV) is 1 to 10,000.

The present invention also relates to (5) the metal-polishing liquid described in any one of (1) to (4) above, wherein the primary particle diameter of the polishing particles is 200 nm or less.

The present invention also relates to (6) the metal-polishing liquid described in anyone of (1) to (5) above, wherein the polishing particles are aggregated and the secondary particle diameter of the aggregate is 200 nm or less.

The present invention also relates to (7) the metal-polishing liquid described in any one of (1) to (6) above, wherein the blending ratio of the polishing particles is 0.001 to 10 mass %.

The present invention also relates to (8) the metal-polishing liquid described in anyone of (1) to (7) above, wherein the polishing particle is at least one of colloidal silica and colloidal silica derivatives.

The present invention also relates to (9) the metal-polishing liquid described in to any one of (1) to (8) above, wherein the pH of the metal-polishing liquid is 2.0 to 7.0.

The present invention also relates to (10) the metal-polishing liquid described in any one of (1) to (9) above, wherein the metal to be polished with the metal-polishing liquid is at least one selected from copper, copper alloys, copper oxide, and copper alloy oxides.

The present invention also relates to (11) a method for polishing a film to be polished by supplying the metal-polishing liquid described in any one of (1) to (10) above onto a polishing cloth of a polishing table while moving the polishing table and a substrate having the film to be polished relatively in the state that the substrate is pressed against the polishing cloth.

The metal-polishing liquid and the polishing method using the same according to the present invention enable production of a highly flattened substrate at high Cu-polishing speed.

The metal-polishing liquid and the polishing method using the same according to the present invention enable reduction of the number of the polishing particles remaining on the polished face after polishing.

### BRIEF DESCRIPTION OF THE DRAWINGS

FIG. 1 is a graph showing the relationships of polishing speed (left axis, solid line) and dishing (right axis, dotted line) with R*A (product of the surface potentials (mV) of the metal to be polished and the polishing particles) in Examples 1 and 2 and Comparative Example 1.

### BEST MODE OF CARRYING OUT THE INVENTION

Hereinafter, the metal-polishing liquid in favorable embodiments of the present invention will be described in detail.

An aspect of the metal-polishing liquid according to the present invention is a metal-polishing liquid containing polishing particles and a chemical component, and it contains polishing particles carrying the charges of surface potential of the same polarity as the charge of surface potential on the reaction layer, adsorption layer or the mixed layer thereof formed by the chemical component on the metal to be polished with the metal-polishing liquid.

The chemical component in the metal-polishing liquid according to the present invention is a component that can form a reaction layer, adsorption layer or the mixed layer thereof on the metal to be polished such as metal oxide dissolving agent, metal anticorrosive, oxidizer, or other additive, i.e., a component other than the polishing particles that act on the metal to be polished mainly mechanically.

The reaction layer formed by the chemical component is a layer in which the chemical component is bound to the metal to be polished by covalent, coordinate, ionic, or other bond. The adsorption layer is a layer in which the chemical component is adsorbed on the metal to be polished by physical adsorption such as hydrogen bonding, van der Waals force, or electrostatic attractive force. In the invention, the surface potential is a ζ potential, as determined by a ζ potential analyzer. The surface potential of the metal to be polished or the surface potential of the reaction layer, adsorption layer or the mixed layer thereof is a ζ potential as determined by measuring the fine particles of the oxide of the metal to be polished, which are dispersed in the metal-polishing liquid containing no polishing particles. For example, when the metal to be polished is Cu, the ζ potential of copper oxide is determined by adding copper oxide (II) powder to a metal-polishing liquid containing no polishing particle, leaving the mixture still, and measuring the supernatant collected. The surface potential of polishing particle is a ζ potential, as determined by measuring the polishing particle in a metal-polishing liquid.

Another aspect of the metal-polishing liquid according to the present invention is a metal-polishing liquid containing polishing particles, wherein the charges of surface potential of the polishing particles and the charges of surface potential of the metal to be polished with the metal-polishing liquid are of the same polarity.

The surface potential of the metal to be polished is a ζ potential as determined by measuring the fine particles of the oxide of the metal to be polished that are added to a metal-polishing liquid containing no polishing particles.

The metal to be polished with the metal-polishing liquid is preferably at least one selected from copper, copper alloys, cupper oxide and oxides of copper alloy. Other favorable metals include tantalum, titanium, tungsten, the compounds thereof, and the like.

Examples of the polishing particles include particles such as of silica, alumina, titania, and cerium oxide; and colloidal silica and/or colloidal silica derivatives are preferable. In addition, the potential of the polishing particles above may be adjusted, for example, by adding trace amounts of metals or by surface modification. The potential-adjusting method is not particularly limited. The polishing particle may be selected properly from commercially available products, by measuring the surface potential thereof according to the metal to be polished.

The colloidal silica derivative is colloidal silica to which trace amounts of metal species are added in sol-gel reaction or of which the surface silanol group is modified chemically; and the preparative method is not particularly limited.

The product of the surface potential of the reaction layer, adsorption layer or the mixed layer of the metal to be polished (mV) formed with the chemical component contained in the metal-polishing liquid and the surface potential of the polishing particle (mV), as determined in a ζ potential analyzer, (hereinafter, referred to as R*A) is preferably 1 to 10,000, more preferably 100 to 10,000, and particularly preferably 250 to 10,000.

Alternatively, the product of the surface potential of the metal to be polished with the metal-polishing liquid (mV) and the surface potential of the polishing particle (mV) (hereinafter, referred to as R*A), as determined in a ζ potential analyzer, is preferably 1 to 10,000, more 100 to 10,000, and particularly 250 to 10,000.

CMP is considered to proceed in such a way that the surface of the metal is polished after the surface is made more brittle and softer, as it is converted into a reaction layer consisting of the chemical component and the polished metal by action of the chemical component. Contact between the brittle soft reaction layer and the polishing particles is preferable avoided for obtaining favorable surface flatness, but addition of the polishing particles is considered preferable for obtaining favorable polishing speed and stabilizing the polishing speed distribution on the substrate surface.

In the present invention, it seems possible to reduce the contact between the reaction layer and the polishing particles by electrostatic repulsive force by using polishing particles having charges of the polarity same as those of the reaction layer, adsorption layer or the mixed layer thereof formed on the metal to be polished and thus, to establish well-balanced favorable polishing speed and polishing speed distribution on the substrate surface by addition of the polishing particles.

In addition, the amount of the polishing particles remaining on the polished face of substrate after the CMP treatment seems to be reduced by electrostatic repulsive force, by using polishing particle having charges of the polarity same as those of the reaction layer, adsorption layer or the mixed layer thereof formed on the metal to be polished.

The primary particle diameter of the polishing particles is preferably 200 nm or less, more preferably 5 to 200 nm, still more preferably 5 to 150 nm, and particular preferably 5 to 100 nm. A primary particle diameter of more than 200 nm may lead to deterioration in flatness.

When the polishing particles are aggregated, the secondary particle diameter is preferably 200 nm or less, more preferably 10 to 200 nm, still more preferably 10 to 150 nm, and particularly preferably 10 to 100 nm. A secondary particle diameter of more than 200 nm may lead to deterioration in flatness. Alternatively, a secondary particle diameter of 10 nm or less may lead to insufficient mechanical removal of the reaction layer by polishing particles and thus to decrease in the CMP speed, and for that reason, caution should be given.

The primary particle diameter of the polishing particles in the invention is determined by using a transmission electron microscope (such as S4700, manufactured by Hitachi Ltd.). The secondary particle diameter is determined by using a light-diffraction-scattering particle size distribution analyzer (such as COULTER N4SD, manufactured by COULTER Electronics).

The blending rate of the polishing particles in the metal-polishing liquid is preferably 0.001 to 10 mass %, more preferably 0.01 to 2.0 mass %, and particularly preferably 0.02 to 1.0 mass %. A blending rate of less than 0.001 mass % may lead to insufficient mechanical removal of the reaction layer by the polishing particles and thus to decrease in the CMP speed, while that of more than 10 mass % to deterioration in surface flatness.

The blending rates of the chemical component and the polishing particles are the values (mass %) with respect to the metal-polishing liquid used during CMP.

Although the metal-polishing liquid according to the present invention is considered effective in improving surface flatness and cleaning efficiency in the entire pH region of the metal-polishing liquid, but the pH is preferably 2.0 to 7.0 and more preferably 3.0 to 5.0.

Examples of the oxidizers to the metal to be polished in the invention include hydrogen peroxide (H₂O₂), nitric acid, potassium periodate, ammonium persulfate, hypochlorous acid, ozone water, and the like, and, among them, hydrogen peroxide is particularly preferable. For example, an alkali metal or an alkali-earth metal may be used for the substrate when the substrate is a silicon substrate carrying elements for an integrated circuit. The metals may be used alone or in combination of two or more. An oxidizer containing no nonvolatile component is preferable, because contamination by halide is undesirable. Among many oxidizers, hydrogen peroxide is preferable from the point of stabilization.

The metal oxide dissolving agent is preferably soluble in water, and it is also preferably at least one selected from organic acids, esters of organic acid, ammonium salts of organic acid, and sulfuric acid. Typical examples of the acids include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, asparagine, aspartic acid, alanine, arginine, isoleucine, glycine, glutamine, glutamic acid, cystine, cysteine, serine, tyrosine, tryptophan, threonine, valine, histidine, hydroxyproline, hydroxylysine, phenylalanine, proline, methionine, lysine, leucine, and the organic ammonium salts thereof, sulfuric acid, nitric acid, ammonia, ammonium salts such as ammonium persulfate, ammonium nitrate and ammonium chloride, chromic acid, or the mixture thereof, and the like. Among them, formic acid, malonic acid, malic acid, tartaric acid, and citric acid are preferable, for laminate films containing a metal layer of at least one selected from copper, copper alloys, copper oxide, and copper alloy oxides. These acids are preferable because they are easily balanced with the protective film-forming agent. Malic acid, tartaric acid, or citric acid is particularly preferable, because it reduces the etching speed effectively while preserving practical CMP speed. These acids may be used alone or in combination of two or more.

The metal anticorrosive is preferably selected from the following group of compounds: ammonia and derivatives thereof such as ammonia, dimethylamine, trimethylamine, triethylamine, propylenediamine, ethylenediaminetetraacetic acid (EDTA), sodium diethyldithiocarbamate and chitosan; imine derivatives such as dithizone, cuproin (2,2′-biquinoline), neocuproin (2,9-dimethyl-1,10-phenanthroline), vasocuproin (2,9-dimethyl-4,7-diphenyl-1,10-phenanthroline) and cuprizone (biscyclohexanonoxalylhydrazone); azoles such as benzimidazole-2-thiol, triazinedithiol, triazinetrithiol, 2-[2-(benzothiazolyl)]thiopropionic acid, 2-[2-(benzothiazolyl)]thiobutyric acid, 2-mercaptobenzothiazole, 1,2,3-triazole, 1,2,4-triazole, 3-amino-1H-1,2,4-triazole, benzotriazole, 1-hydroxybenzotriazole, 1-dihydroxypropylbenzotriazole, 2,3-dicarboxypropylbenzotriazole, 4-hydroxybenzotriazole, 4-carboxyl-1H-benzotriazole, 4-carboxyl-1H-benzotriazole methyl ester, 4-carboxyl-1H-benzotriazole butyl ester, 4-carboxyl-IH-benzotriazole octyl ester, 5-hexylbenzotriazole, [1,2,3-benzotriazolyl-1-methyl] [1,2,4-triazolyl-1-methyl] [2-ethylhexyl]amine, tolyltriazole, naphthotriazole, and bis[(1-benzotriazolyl)methyl]phosphonic acid; mercaptans such as nonylmercaptan and dodecylmercaptan; glucose, cellulose, and the like. Among them, benzotriazole, triazole and the derivatives thereof are preferable, from the point of the balance between high polishing speed and low etching speed.

As the other additives in the invention, at least one water-soluble polymer selected from the following group of resins is favorably used: polymers having a carboxyl group-containing monomer as the basic structural unit and the salts thereof such as polyacrylic acid, ammonium polyacrylate salt, sodium polyacrylate salt, polymethacrylic acid, ammonium polymethacrylate salt, sodium polymethacrylate salt, or polyacrylamide or the like; and polymers such as polyvinyl alcohol and polyvinylpyrrolidone having a vinyl group-containing monomer as the basic structural unit. For example when the substrate to be used is a silicon substrate for semi-conductor integrated circuit, contamination by an alkali metal or alkali-earth metal or halide is undesirable and therefore an acid or an ammonium salt thereof is favorably used. It is possible to achieve high polishing speed and favorable dishing resistance, by adding such a water-soluble polymer.

The polishing method according to the present invention is a method for polishing a film to be polished by supplying the metal-polishing liquid described above onto a polishing cloth of a polishing table while moving the polishing table and a substrate having the film to be polished relatively in the state that the substrate is pressed against the polishing cloth.

A polishing device that can be used may be an ordinary polishing device having a holder for holding a substrate, and a polishing table to which a polishing cloth (polishing pad) can be stuck and to which a motor or the like that can give a variable rotation number are fitted. The polishing cloth is not particularly limited, and ordinary nonwoven cloth, foamed polyurethane, porous fluorine-contained resin or the like can be used. Conditions for the polishing are not particularly limited. The rotating speed of the polishing table is preferably as low as 200 rpm or less so as not to cause the substrate to fly out.

The polishing pressure of the substrate having the film to be polished against the polishing cloth is preferably from 5 to 100 kPa. The pressure is more preferably from 10 to 50 kPa in order to cause evenness of the polishing speed in a wafer face and the flatness of a pattern to be satisfied. While the substrate is polished, the metal-polishing liquid is preferably continuously supplied on to the polishing cloth by a pump or the like. The supplied amount thereof is not limited. Preferably, the surface of the polishing cloth should be covered with the metal-polishing liquid at any time. Preferably, the substrate after the polishing is sufficiently washed with flowing water, water drops on the substrate are swept off by use of a spin drier or the like, and then the substrate is dried.

The film to be polished is preferably a film of at least one selected from the copper, copper alloys, copper oxide, and copper alloy oxides as described above. Other favorable metals include tantalum, titanium, tungsten, the compounds thereof, and the like.

The metal-polishing liquid and the polishing method according to the present invention are applicable, for example, in LSI production processes, and in particular, in polishing a wiring material such as copper-alloy thin film on a substrate to form implanted wiring in the step of forming multilayer wiring. They can also be used in polishing substrates such as of magnetism head.

### EXAMPLES

Hereinafter, the present invention will be described specifically with reference to Examples, but it should be understood that the present invention is not restricted by these Examples.

### Examples 1 to 4 and Comparative Example 1

Metal-Polishing liquid 1

The metal-polishing liquid 1 used contains an organic acid (metal oxide dissolving agent) at 1 mass % or less, a nitrogen-containing cyclic compound (metal anticorrosive) at 0.5 mass % or less, a water-soluble polymer (additive) at 2 mass % or less, hydrogen peroxide (oxidizer) at 10 mass % or less, and water. The polishing particles shown in Table 1, different in surface potential from each other, having a primary particle diameter in the range of the average (shown in Table 1) ±10% and a secondary particle diameter of the average (shown in Table 1) ±15% were added to the metal-polishing liquid 1.

In Examples 1 to 4 and Comparative Example 1, a test substrate was polished chemical-mechanically by using the metal-polishing liquids 1 respectively containing polishing particles different in surface potential from each other under the condition described below.

### Example 5 and Comparative Example 2

Metal-Polishing Liquid 2

The metal-polishing liquid 2 used contains a metal oxide dissolving agent at 0.5 mass % or less, a nitrogen-containing cyclic compound (metal anticorrosive) at 0.3 mass % or less, a water-soluble polymer (additive) at 0.5 mass % or less, hydrogen peroxide (oxidizer) at 10 mass % or less, and water. The polishing particles shown in Table 1, different in surface potential from each other, having a primary particle diameter in the range of the average (shown in Table 1) ±10% and a secondary particle diameter of the average (shown in Table 1) ±15% were added to the metal-polishing liquid 2. In Example 5 and Comparative Example 2, a test substrate was polished chemical-mechanically by using the metal-polishing liquids 2 respectively containing polishing particles different in surface potential from each other under the condition described below.

### Example 6 and Comparative Example 3

Metal-Polishing Liquid 3

The metal-polishing liquid 3 used contains an organic acid (metal oxide dissolving agent) at 1 mass % or less, a water-soluble polymer (additive) at 2 mass % or less, hydrogen peroxide (oxidizer) at 10 mass % or less, and water. The polishing particles shown in Table 1, different in surface potential from each other, having a primary particle diameter in the range of the average (shown in Table 1) ±10% and a secondary particle diameter of the average (shown in Table 1) ±15% were added to the metal-polishing liquid 3.

In Example 6 and Comparative Example 3, a test substrate was polished chemical-mechanically by using the metal-polishing liquids 3 respectively containing polishing particles (shown in Table 1) different in surface potential from each other under the condition described below.

(Method of Measuring Surface Potential)

In the invention, the surface potential of the reaction layer, adsorption layer or the mixed layer thereof formed on the metal to be polished by the chemical component (hereinafter, referred to also as ζ potential of the metal to be polished) and the surface potential of the polishing particle in the polishing liquid were determined in an ζ potential analyzer described below using a laser Doppler method as its measurement principle. When the metal to be polished is Cu, the ζ potential of the metal Cu to be polished was determined by adding 1 mass % of copper oxide (II) powder (manufactured by Kanto Kagaku Co. Inc.) to a metal-polishing liquid containing no polishing particle, allowing the mixture to stand still for 5 minutes, collecting the supernatant with a pipette, and injecting 5 milliliter of it into the analytical cell with a syringe. The surface potential of the polishing particle (hereinafter, referred to also as ζ potential of polishing particle) was determined, after the particles were dispersed in the metal-polishing liquid at the blending rates shown in Table 1.

Analyzer: ZETASIZER 3000HS (manufactured by MALVERN Instruments Ltd.)

Measuring condition: temperature: 25° C.

Refractive index of dispersion medium: 1.331

Viscosity of dispersion medium: 0.893 cP

(Method of Measuring Polishing-Particle Diameter)

The primary particle diameter of the polishing particles used in the present invention was determined by using a transmission electron microscope (S4700, manufactured by Hitachi Ltd.) at a magnification of 100,000 to 500,000 times, after the polishing liquid was so dried that the particles did not aggregate on the micro mesh. The secondary particles of the polishing particles were measured five times by using a light-diffraction-scattering particle size distribution analyzer (COULTER N4SD, manufactured by COULTER Electronics) under the condition of a measurement temperature of 20° C. and an intensity (corresponding to scattering intensity and turbidity) in the range of 5E+04 to 4E+05, after the particles are diluted with purified water when the intensity is too high, and the unimodal average was obtained. The other parameters and conditions used are as follows: solvent refractive index: 1.333 (water); particle refractive index setting: unknown; solvent viscosity: 1.005 cp (water); Run Time: 200 sec; and laser incident angle: 90°.

(Substrate to be Polished, Carrying Copper Wiring)

For evaluation of dishing, used was a silicon substrate (SEMATECH 854 wafer) carrying an insulation layer having a pattern formed with channels of 500 nm in depth on the surface and additionally a TaN film of 25 nm and a Cu film of 10 nm in thickness deposited by sputtering and a Cu layer of 1.2 μm in thickness deposited by electrolytic plating. The Cu-polishing speed was determined from the original thickness of the substrate to be polished and the polishing time.

(Polishing Condition)

Polishing pad: IC-1400 (manufactured by Rodel Inc.)

Polishing pressure: 13.8 kPa

Polishing liquid feed rate: 200 ml

(Washing After CMP)

After CMP treatment, the substrate was cleaned with a PVA brush and ultrasonicated water, and dried with a spin dryer.

(Test Items of Polished Substrate)

Cu-polishing speed: the difference in thickness between before and after CMP of a copper film was calculated from the change in electric resistance.

Dishing: the dishing was evaluated by scanning a region of 100 μm in wiring width and 100 μm in wiring space width in a contact profilometer (DECKTAK V200-Si, manufactured by Veeco Instruments.).

Residual-particle number: the number of polishing particles remaining on the polished face of the substrate was determined by using Surfscan 6220 manufactured by KLA-Tencor Corporation.

The polishing scratches formed on the substrate after CMP were observed visually or under an optical or electron microscope. As a result, there was no polishing scratch observed.

The evaluation results on the Cu-polishing speed, dishing and residual-particle number of the substrates in Examples 1 to 6 and Comparative Examples 1 to 3 are summarized in Table 1.

TABLE 1

| | | | | | | | Compara- | Compara- | Compara- |
|---|---|---|---|---|---|---|---|---|---|
| | | | | | | | tive | tive | tive |
| Item | Example 1 | Example 2 | Example 3 | Example 4 | Example 5 | Example 6 | Example 1 | Example 2 | Example 3 |
| ζ potential of | −25 | −25 | −25 | −25 | −37 | −45 | −25 | −37 | −45 |
| metal to be | | | | | | | | | |
| polished (mV) | | | | | | | | | |
| ζ potential of | −14 | −25 | −16 | −29 | −12 | −25 | 5 | 1 | 1 |
| polishing | | | | | | | | | |
| particle (mV) | | | | | | | | | |
| R*A | 350 | 625 | 400 | 725 | 444 | 1125 | −125 | −37 | −45 |
| Primary particle | 30 | 30 | 40 | 105 | 14 | 30 | 30 | 15 | 30 |
| diameter of | | | | | | | | | |
| polishing | | | | | | | | | |
| particles (nm) | | | | | | | | | |
| Secondary | 60 | 61 | 50 | 220 | 33 | 60 | 58 | 30 | 58 |
| particle | | | | | | | | | |
| diameter of | | | | | | | | | |
| polishing | | | | | | | | | |
| particles (nm) | | | | | | | | | |
| Blending rate of | 0.5 | 0.5 | 0.3 | 0.3 | 0.8 | 0.3 | 0.3 | 0.8 | 0.3 |
| polishing | | | | | | | | | |
| particles | | | | | | | | | |
| (mass %) | | | | | | | | | |
| Kind of | Colloidal | Colloidal | Titania | Colloidal | Colloidal | Colloidal | Colloidal | Colloidal | Colloidal |
| polishing | silica | silica | | silica | silica | silica | silica | silica | silica |
| particles | derivative | derivative | | derivative | derivative | derivative | | | |
| pH of Metal- | 3.5 | 3.5 | 3.5 | 3.5 | 6.8 | 3.5 | 3.5 | 6.8 | 3.5 |
| polishing | | | | | | | | | |
| solution | | | | | | | | | |
| Cu-polishing | 640 | 600 | 650 | 660 | 240 | 950 | 650 | 250 | 1100 |
| speed (nm/min) | | | | | | | | | |
| Dishing (nm) | 50 | 35 | 45 | 85 | 30 | 150 | 110 | 50 | 280 |
| Residual- | 1500 | 800 | 1000 | 700 | 900 | 500 | 10000 | 8000 | 8000 |
| particle number | | | | | | | | | |

Obviously, the substrate in Example 1 has a Cu-polishing speed similar to but a dishing depth significantly reduced from those of the substrate in Comparative Example 1, which is polished with a polishing liquid containing polishing particles similar to Example 1 in particle diameter and having surface charges different in polarity from those of the metal to be polished. The substrate in Example 2 is polished with a polishing liquid containing polishing particles having a diameter similar to and a surface potential greater than those in Example 1. Obviously, the substrate is improved in dishing resistance from the Example 1. The substrate in Example 3 contains a titania derivative as polishing particles. The substrates in Examples are obviously favorable in dishing resistance, independently of the kind of the polishing particles used. As shown in Example 4, increase in the primary and secondary particle diameters of polishing particles leads to deterioration in dishing resistance, and thus, caution should be given. Comparison of the substrates obtained in Example 5 and Comparative Example 2 reveals that the advantageous effect of the present invention does not depend on pH. The substrate in Example 6 differs from those in Examples 1 to 5, in that the polishing liquid contains no metal anticorrosive. Although the polishing speed and dishing are higher because of absence of the metal anticorrosive, the substrate in Example 6 is obviously improved in dishing resistance from the substrate in Comparative Example 3 which was process with a polishing liquid containing a similar chemical component. Comparison of the substrates obtained in Examples 1 to 6 and in Comparative Examples 1 to 3 shows that the number of residual particles decreases when the metal to be polished and the polishing particles have a ζ potential of the same polarity and the value R*A is greater.

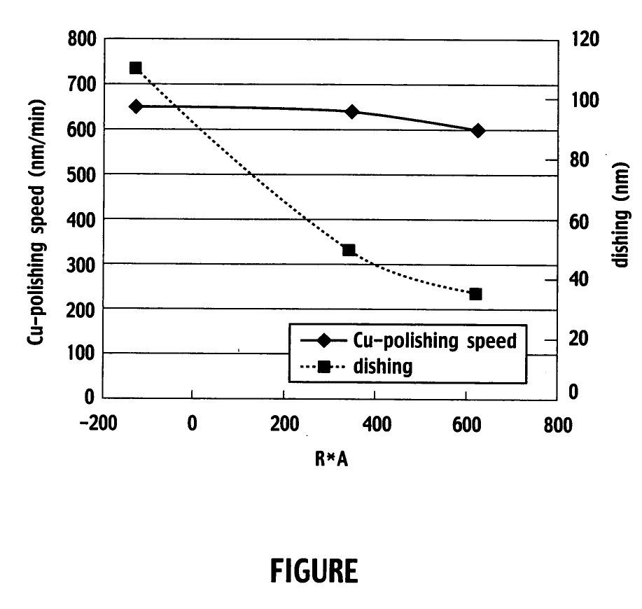

FIG. 1 is a graph showing the relationship between the polishing speed and dishing and the R*A value in Examples 1 and 2 and Comparative Example 1.

As apparent from FIG. 1, increase in the R*A value leads to decrease of dishing. On the other hand, there is no distinct decrease in the Cu-polishing speed. Thus, it is possible to reduce dishing while preserving the Cu-polishing speed, by raising the R*A value.

In addition, polishing particles having a negative surface potential were used in the present Examples because the surface potential of the metal to be polished was negatively charged, and it is seemingly possible to obtain the same advantageous effects of the present invention by using polishing particles having a positive surface potential when the surface potential of the metal to be polished is positive.

### INDUSTRIAL APPLICABILITY

The metal-polishing liquid and the polishing method using the same according to the present invention enable production of a highly flattened face of substrate at high Cu-polishing speed.

In addition, the metal-polishing liquid and the polishing method using the same according to the present invention enable reduction of the number of the polishing particles remaining on the polished face after polishing.

1. A metal-polishing liquid, comprising polishing particles and a chemical component, wherein
the polishing particles have charges of surface potential of the same polarity as the charges of surface potential on the reaction layer, adsorption layer or the mixed layer thereof formed with the chemical component on a metal to be polished with the metal-polishing liquid.

2. A metal-polishing liquid, comprising polishing particle, wherein
the charges of surface potential of the polishing particles and the charges of surface potential on a metal to be polished with the metal-polishing liquid are of the same polarity.

3. The metal-polishing liquid according to claim 1, wherein the product of the surface potential of the reaction layer, adsorption layer or the mixed layer thereof (mV) and the surface potential of the polishing particle (mV) is 1 to 10,000.

4. The metal-polishing liquid according to claim 2, wherein the product of the surface potential of the metal to be polished (mV) and the surface potential of the polishing particle (mV) is 1 to 10,000.

5. The metal-polishing liquid according to any one of claims 1 to 4, wherein the primary particle diameter of the polishing particles is 200 nm or less.

6. The metal-polishing liquid according to any one of claims 1 to 4, wherein the polishing particles are aggregated and the secondary particle diameter of the aggregate is 200 nm or less.

7. The metal-polishing liquid according to any one of claims 1 to 4, wherein the blending ratio of the polishing particles is 0.001 to 10 mass %.

8. The metal-polishing liquid according to any one of claims 1 to 4, wherein the polishing particle is at least one of colloidal silica and colloidal silica derivatives.

9. The metal-polishing liquid according to any one of claims 1 to 4, wherein the pH of the metal-polishing liquid is 2.0 to 7.0.

10. The metal-polishing liquid according to any one of claims 1 to 4, wherein the metal to be polished with the metal-polishing liquid is at least one selected from copper, copper alloys, copper oxide, and copper alloy oxides.

11. A method for polishing a film to be polished by supplying the metal-polishing liquid according to any one of claims 1 to 4 onto a polishing cloth of a polishing table while moving the polishing table and a substrate having the film to be polished relatively in the state that the substrate is pressed against the polishing cloth.
